(19) United States
(12) Patent Application Publication
(10) Pub. No.: US 2007/0164390 A1
(43) Pub. Date: Jul. 19, 2007

(54) Silicon nitride passivation layers having oxidized interface

(76) Inventors: Irina V. Vasilyeva, Boise, ID (US); Richard B. Pasta, Boise, ID (US)

Correspondence Address: DINSMORE & SHOHL LLP, ONE DAYTON CENTRE, ONE SOUTH MAIN STREET, SUITE 1300, DAYTON, OH, 45402-2023, US

(21) Appl. No.: 11/635,414

(22) Filed: Dec. 7, 2006

Related U.S. Application Data
(62) Division of application No. 11/180,830, filed on Jul. 13, 2005.

(51) Int. Cl. H01L 29/00

(52) U.S. Cl. 257/499

(57) ABSTRACT

A method of forming a passivation film on a semiconductor substrate is provided and includes forming a first silicon nitride containing layer on the substrate, oxidizing the surface of the first silicon nitride containing layer, and forming a second silicon nitride containing layer on the oxidized surface of the first silicon nitride containing layer. The oxidized surface may be formed by exposing the first silicon nitride containing layer to an oxygen containing gas plasma.

### CROSS REFERENCE TO RELATED APPLICATION

This application is a divisional of U.S. patent application Ser. No. 11/180,830, filed Jul. 13, 2005.

### FIELD OF THE INVENTION

The present invention relates to semiconductor devices, and more particularly, to multi-layer passivation films on semiconductor devices.

### BACKGROUND OF THE INVENTION

During the fabrication of semiconductor devices, a dielectric layer is typically formed over the top surface of the semiconductor device. This dielectric layer is referred to as a passivation layer, and acts as an insulating protective layer which prevents mechanical and chemical damage during assembly and packaging. Passivation layers should be impermeable to moisture and alkali metals such as sodium. Passivation layers should also exhibit optimized stress and have thermal properties similar to those of neighboring materials in the semiconductor device.

Passivation layers are particularly important in the manufacture of integrated circuit memories, such as dynamic random access memory (“DRAM”) devices. In these devices, one of the final layers formed on the semiconductor wafer is a conductive metal layer which not only provides interconnections within the device's circuitry but also provides bonding pads which are used to connect the circuitry to external devices. Typically, the metal layer is patterned to form a plurality of spaced conductive runners. After these conductive runners have been formed, a passivation layer is deposited over the conductive runners and other portions of the semiconductor substrate. Thereafter, the passivation layer is etched in order to remove portions of this layer and expose the bonding pad regions of the conductive runners. Thus, in integrated circuit memories the passivation layer should be chosen so that it may be patterned by photolithography and other techniques.

Passivation layers (or films) may be formed from a variety of materials using a variety of techniques. In addition, the passivation layer may comprise multiple layers of the same or different materials in order to provide the desired properties. However, such multi-layer passivation films typically require multiple processing steps which increase manufacturing costs. Accordingly, there remains a need in this art to provide more economical methods of forming such passivation layers.

### SUMMARY OF THE INVENTION

Embodiments of the present invention meet that need by providing methods which improve the refresh rate of semiconductor devices during the fabrication process. Specifically, embodiments of the present invention increase wafer throughput without adversely affecting the wafer die and passivation film properties.

In accordance with one aspect of the present invention, a method of forming a passivation film on a semiconductor substrate is provided and includes forming a first silicon nitride containing layer on the substrate, oxidizing the surface of the first silicon nitride containing layer, and forming a second silicon nitride containing layer on the oxidized surface of the first silicon nitride containing layer. In a preferred form, the surface of the first silicon nitride containing layer is oxidized by exposure to an oxygen-containing gas plasma such as, for example, a nitrous oxide plasma. In another embodiment, the surface of the first silicon nitride containing layer is oxidized by exposure to an oxygen containing gas such as, for example, oxygen, ozone, or the atmosphere. By “silicon nitride containing” it is meant to include not only silicon nitride (Si₃N₄) but also other nitrides and hydrides (SiNₓH_{y}) of silicon.

Preferably, the first and second silicon nitride containing layers are formed using plasma enhanced chemical vapor deposition. In a preferred form, the first and second silicon nitride containing layers are formed by providing a gas mixture comprising N₂, SiH₄ and, optionally, NH₃ and energizing said gas mixture to create a gas plasma and form a silicon nitride containing layer on said semiconductor substrate. In certain embodiments, the flow rate of N₂ is from between about 10 to about 20,000 sccm, and the flow rate of SiH₄ is from between about 10 to about 1000 sccm. Where NH₃ is present, the flow rate of said NH₃ is from between about 0.1 to about 1000 sccm.

Typically, where the energizing step takes place in a PECVD reaction chamber, the method includes applying from between about 100 to about 1500 watts of RF power to the PECVD chamber while the chamber is maintained at a pressure of from between about 1 to about 50 Torr, and a temperature of from between about 100° to about 550° C.

The passivation layer preferably comprises first and second silicon nitride layers wherein the first silicon nitride containing layer has a thickness of from between about 2000 to about 8000 angstroms, most preferably about 6000 angstroms, and the second silicon nitride containing layer has a thickness of from between about 2000 to about 8000 angstroms, most preferably about 6000 angstroms. In a preferred embodiment, the semiconductor substrate comprises a DRAM memory device.

Embodiments of the present invention provide a semiconductor device that includes a substrate and a passivation film on the substrate, wherein the passivation film comprises first and second silicon nitride containing layers and an oxidized interface between said first and second silicon nitride containing layers. The oxidized interface is preferably formed by exposing the surface of said first silicon nitride containing layer to an oxygen-containing plasma.

The process provides methods which improve the refresh rate of semiconductor devices during the fabrication process. Specifically, preferred embodiments of the present invention increase wafer throughput without adversely affecting the wafer die properties by enabling the formation of the oxidized interface in a single pass of the wafer through a reaction chamber. These and other features and advantages of the invention will become apparent from the following detailed description, the accompanying drawings, and the appended claims.

### BRIEF DESCRIPTION OF THE DRAWINGS

The following detailed description will be more fully understood in view of the drawings in which:

FIG. 1 is a schematic illustration of a fragment of a semiconductor device having a passivation film formed thereon; and

FIG. 2 is a schematic illustration of a fragment of a DRAM memory device having a passivation film formed thereon.

The embodiments set forth in the drawing are illustrative in nature and are not intended to be limiting of the invention which is defined by the claims. Moreover, individual features of the drawings and the invention will be more fully apparent and understood in view of the detailed description.

### DETAILED DESCRIPTION

Embodiments of the present invention are directed to methods of forming a passivation film on a semiconductor substrate. The passivation film comprises at least first and second silicon nitride containing layers deposited sequentially onto the semiconductor substrate, wherein the upper surface of the first layer is oxidized prior to deposition of the second layer. In this manner, an oxidized interface is provided between the first and second silicon nitride containing layers. In a preferred embodiment, plasma enhanced chemical vapor deposition (“PECVD”) is used to form the silicon nitride containing layers as well as to oxidize the surface of the first silicon nitride layer by exposing the surface of the first silicon nitride layer to an oxygen-containing plasma.

PECVD is a technique used during semiconductor fabrication to deposit thin films of various materials onto a substrate. In general, a substrate may be placed in a PECVD reaction chamber, the chamber is placed under a vacuum, a precursor deposition gas (typically a mixture of gases) is introduced into the chamber, a plasma is generated from the precursor gas, and a layer of material is deposited onto the substrate. In PECVD systems, the plasma is typically, although not exclusively, generated by application of an RF field to the gas within the chamber. A suitable PECVD reactor for use in the practice of embodiments of the present invention comprises a Producer® twin chamber reactor available from Applied Materials, Inc.

As used herein, the term “substrate” (or “semiconductor substrate”) includes any structure comprising semiconductor material, including bulk semiconductor materials such as a semiconductor wafer (either alone or in assemblies comprising other materials thereon), and semiconductor material layers (either alone or in assemblies comprising other materials). In addition, the term “substrate” also includes any supporting structure including, but not limited to, the semiconductor substrates described above. The term substrate may also refer to one or more semiconductor layers or structures which includes active or operable portions of semiconductor devices, as well as semiconductor structures during processing (and may include other layers, such as silicon-on-insulator (SOI), etc. that have been fabricated thereupon).

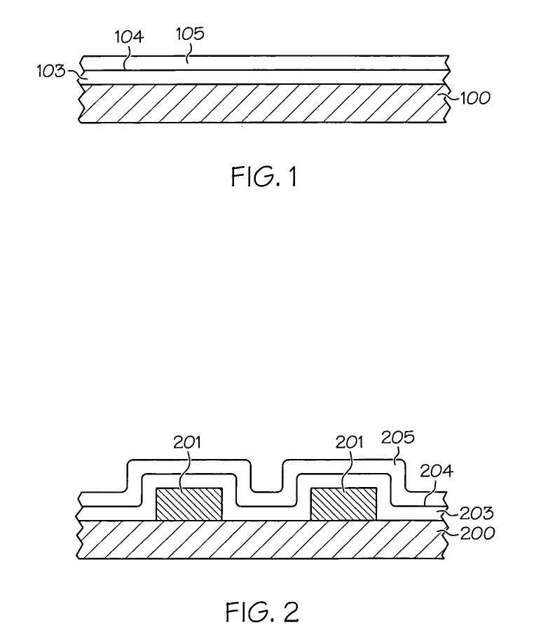

FIG. 1 depicts an exemplary semiconductor substrate having a passivation film formed thereon in accordance with an embodiment of the present invention. In FIG. 1, the semiconductor device comprises a substrate 100, such as a semiconductor wafer. Because the construction of the substrate is not important to an understanding of the invention, details of that construction have been omitted. However, it should be understood that substrate 100 may comprise an advanced multilevel logic or memory device. The passivation film in the exemplary embodiment of FIG. 1 comprises first and second silicon nitride containing layers 103 and 105, respectively, with an oxidized interface 104 therebetween. The oxidized interface 104 may be provided by oxidizing the surface of the first silicon nitride containing layer 103 and thereafter forming the second silicon nitride containing layer 105 on the oxidized surface 104 of the first silicon nitride containing layer 103.

Previously, double layer passivation films have been produced by first depositing a silicon nitride containing layer on the substrate by PECVD in a sealed reaction chamber, removing the substrate from the chamber, and exposing the layer of deposited material to the atmosphere such that the surface of the first silicon nitride containing layer becomes oxidized. The substrate is then returned to the reaction chamber where a second silicon nitride containing layer is deposited on the oxidized surface of the first silicon nitride containing layer. While acceptable results can be achieved, this process adds steps to the fabrication process, increasing the time needed to complete the fabrication of the semiconductor device.

In embodiments of the present invention, PECVD may be used to deposit the silicon nitride containing layers and to provide the oxidized interface between these layers. Advantageously, the substrate need not be removed from the PECVD chamber in order to oxidize the surface of the first silicon nitride containing layer, and the vacuum within the chamber may be maintained. The oxidized interface between silicon nitride containing layers is provided by exposing the surface of the first silicon nitride containing layer to an oxygen-containing plasma within the PECVD chamber. The formation of the first silicon nitride containing layer, oxidation of the surface of the first silicon nitride containing layer and formation of the second silicon nitride containing layer on the oxidized interface may be performed sequentially in the same PECVD chamber without removing the substrate from the PECVD chamber until after formation of the second silicon nitride containing layer. In this manner, processing time is significantly reduced without adversely affecting the performance of the passivation film or the underlying substrate. In fact, applicants have found that practice of embodiments of the present invention allow for a reduction in the thickness of the passivation film while still maintaining the desired properties of abrasion and moisture resistance.

The described methods may be used to form films, particularly passivation films, on a variety of semiconductor devices. For example, FIG. 2 is a simplified schematic illustration of a portion of a dynamic random access memory (“DRAM”) device. In particular, the DRAM device shown in Fig. includes a substrate 200 which includes a plurality or array of parallel spaced conductive runners 201. Typically, a DRAM device includes two sets of a plurality of spaced conductive runners that are generally perpendicular to each other and intersect each other at locations adjacent to the contacts connected to memory cells formed in underlying layers of the device. As in the previously described embodiment, the passivation film may be formed on the substrate, particularly on the conductive runners 201 of the substrate as shown in FIG. 2.

The described silicon nitride containing passivation films may be deposited using a variety of precursor gas compositions and a variety of PECVD process parameters. In one embodiment, the precursor gas may comprise a mixture of N₂, SiH₄ and, optionally, NH₃. It is also contemplated that the same mixture of gases may be used in the formation of both silicon nitride containing layers. Suitable PECVD process parameters for one embodiment include deposition of the silicon nitride containing material at a temperature of from about 100° to about 550° C., a pressure of from about 1 to about 50 torr, and an RF power rating of from about 100 to 1500 watts. The flow rates of the precursor gases may be from about 10 to about 1000 sccm SiH₄, from about 10 to about 20,000 sccm N₂, and, optionally, from about 0.1 to about 1000 sccm NH₃.

As previously described, after a first silicon nitride containing layer has been deposited onto the substrate by PECVD, the surface of the first layer is oxidized, preferably by exposure to an oxygen-containing plasma. Oxidation may be accomplished without removing the substrate from the PECVD chamber and without breaking the vacuum in the PECVD chamber. In one exemplary embodiment, the substrate may be exposed to an N₂O plasma in the PECVD chamber. Other oxygen-containing gas plasmas may be utilized. For example, the surface of the first silicon nitride containing layer may be oxidized in a PECVD reaction chamber using a N₂O flow rate of from about 200 sccm to about 500 sccm, a temperature about 100° to about 500° C., a pressure of from about 1 to about 50 torr, and an RF power rating of from about 50 to about 500 watts for a time of from between about 3 to about 30 seconds.

After the surface of the first silicon nitride containing layer has been oxidized, the second silicon nitride containing layer is deposited onto the oxidized surface by PECVD. The same precursor gas mixture as used for depositing the first silicon nitride containing layer may be used to deposit the second layer, or a different gas mixture may be used. In addition, the thickness of the resulting second silicon nitride layer may be the same as or different from the first silicon nitride layer (greater or less than). Typically, the passivation layer comprises first and second silicon nitride containing layers wherein the first silicon nitride containing layer has a thickness of from between about 2000 to about 8000 angstroms, most preferably about 6000 angstroms, and the second silicon nitride containing layer has a thickness of from between about 2000 to about 8000 angstroms, most preferably about 6000 angstroms. Alternatively, the first silicon nitride containing layer may have a thickness of about 3000 angstroms and the second silicon nitride containing layer may have a thickness of about 7000 angstroms.

The specific illustrations and embodiments described herein are exemplary only in nature and are not intended to be limiting of the invention defined by the claims. Further embodiments and examples will be apparent to one of ordinary skill in the art in view of this specification and are within the scope of the claimed invention. For example, although the present invention has been described with respect to the formation of a two-layer passivation film, the present invention is not so limited. In particular, more than two passivation layers may be formed, and the interface between these additional layers may or may not be oxidized.

1. A semiconductor device comprising a substrate and a passivation film on said substrate, wherein said passivation film comprises a first silicon nitride containing layer having an oxidized surface and a second silicon nitride containing layer on said first silicon nitride containing layer and forming an oxidized interface between said first and second silicon nitride containing layers.

2. A semiconductor device as claimed in claim 1 wherein, said oxidized interface is formed by exposing the surface of said first silicon nitride containing layer to an oxygen-containing plasma.

3. A semiconductor device as claimed in claim 1 wherein said first silicon nitride containing layer has a thickness of from between about 4000 to about 8000 angstroms, and said second silicon nitride containing layer has a thickness of from between about 4000 to about 8000 angstroms.

4. A semiconductor device as claimed in claim 1, wherein said semiconductor substrate comprises a DRAM memory device.

5. A semiconductor device comprising a substrate and a passivation film on said substrate, said passivation film formed by depositing a first silicon nitride containing layer on said substrate, oxidizing the surface of said first silicon nitride containing layer, and forming a second silicon nitride containing layer on the oxidized surface of said first silicon nitride containing layer.

6. A semiconductor device as claimed in claim 5, wherein said surface of said first silicon nitride containing layer is oxidized by exposure to an oxygen-containing gas plasma.

7. A semiconductor device as claimed in claim 6, wherein said oxygen-containing gas plasma comprises a nitrous oxide plasma.

8. A semiconductor device as claimed in claim 5, wherein said surface of said first silicon nitride containing layer is oxidized by exposure to an oxygen containing gas.

9. A semiconductor device as claimed in claim 5, wherein said first and second silicon nitride containing layers are formed using plasma enhanced chemical vapor deposition.

10. A semiconductor device comprising a semiconductor substrate and a passivation film on said semiconductor substrate, said passivation film formed by depositing a first silicon nitride containing layer on said semiconductor substrate, oxidizing the surface of said first silicon nitride containing layer by exposing said first silicon nitride containing layer to an oxygen-containing plasma, and forming a second silicon nitride containing layer on the oxidized surface of said first silicon nitride containing layer.

11. A semiconductor device as claimed in claim 10, wherein said surface of said first silicon nitride containing layer is oxidized by exposure to an oxygen-containing gas plasma.

12. A semiconductor device as claimed in claim 11, wherein said oxygen-containing gas plasma comprises a nitrous oxide plasma.

13. A semiconductor device comprising a semiconductor substrate and a passivation film on said semiconductor substrate, said passivation film formed by providing a semiconductor substrate in a reaction chamber, forming a first silicon nitride containing layer on said semiconductor substrate, oxidizing the surface of said first silicon nitride containing layer by exposing said first silicon nitride containing layer to an oxygen-containing plasma in said reaction chamber, and forming a second silicon nitride containing layer on the oxidized surface of said first silicon nitride containing layer.

14. A semiconductor device as claimed in claim 13, wherein said oxygen-containing gas plasma comprises a nitrous oxide plasma.
